(19) United States
(12) Patent Application Publication
(10) Pub. No.: US 2026/0122738 A1
(43) Pub. Date: Apr. 30, 2026

(54) FLASH IRRADIATION APPARATUS

(71) Applicant: Ushio Denki Kabushiki Kaisha, Tokyo (JP)

(72) Inventors: Masahiko KASE, Tokyo (JP); Masayuki KONISHI, Tokyo (JP); Haruka UEMATSU, Tokyo (JP)

(73) Assignee: Ushio Denki Kabushiki Kaisha, Tokyo (JP)

(21) Appl. No.: 19/367,789

(22) Filed: Oct. 23, 2025

(30) Foreign Application Priority Data
Oct. 25, 2024 (JP) 2024-188384

(51) Int. Cl. H05B 41/34; H10P 72/00

(52) U.S. Cl. CPC H05B 41/34; H10P 72/0436

(57) ABSTRACT

A flash irradiation apparatus is provided that suppresses output reduction when flash irradiation is repeated and achieves higher flash energy efficiency than conventional apparatuses. The apparatus includes: a flash lamp including a first and a second terminals; a capacitor including a first and a second electrodes; first and second switching elements connected in parallel to control connection between the flash lamp and the capacitor; and a controller that controls the first and second switching elements. The controller executes: a first control in which on-off control of the second switching element is repeatedly executed at high speed while the first switching element is off state to apply a charged voltage from the capacitor to the flash lamp; and a second control in which the first switching element is turned on during the first control to generate a main discharge based on the capacitor's residual voltage.

### CROSS-REFERENCE TO RELATED APPLICATIONS

This application claims priority of Japan Patent Application No. 2024-188384, which was filed on Oct. 25, 2024, and which is incorporated herein in its entirety by reference.

### BACKGROUND OF THE INVENTION

### Field of the Invention

The present invention relates to a flash irradiation apparatus.

### Description of the Related Art

Conventionally, flash irradiation by a flash lamp has been performed as heat treatment of a semiconductor wafer or heat treatment in a manufacturing process of printable electronics or the like. In recent years in particular, with the miniaturization of semiconductor processes, a method of instantaneous heat treatment using a flash irradiation apparatus has attracted attention as a method for activating implanted impurities while suppressing diffusion caused by prolonged heating.

In a flash lamp, a portion of a glass material constituting a light-emitting tube evaporates due to a flash, or an oxygen component contained in the glass material is desorbed, so that cloudiness may occur on the inner wall of the light-emitting tube. The cloudiness tends to be noticeable when the flash irradiation of the flash lamp is repeated, and causes a decrease in the output of the flash lamp.

Therefore, the present applicant has developed a lighting device for a flash lamp, for example, as shown in Patent Document 1 below. Patent Document 1 discloses a lamp lighting device capable of performing flash irradiation in a state where a simmer discharge is formed near a tube axis of a light-emitting tube from the viewpoint of suppressing cloudiness of the inner wall of the light-emitting tube occurring when flash irradiation is repeated.

### PRIOR ART DOCUMENT

### Patent Document

Patent Document 1: JP-A-2009-164080

### SUMMARY OF THE INVENTION

FIG. 12 is a diagram schematically illustrating a circuit configuration of a lamp lighting device according to Patent Document 1. As illustrated in FIG. 12, a lamp lighting device 100 includes a flash lamp 70, a capacitor 80, an inductor 81, a resistor 82, a switching element 83, a trigger electrode 90, and a trigger circuit 91.

FIG. 13 is a view schematically illustrating the configuration of the flash lamp 70 according to FIG. 12. In FIG. 13, an X-Y-Z coordinate system in which a vertically upward direction is a Z direction and a plane orthogonal to the Z direction is an X-Y plane is also illustrated. As illustrated in FIGS. 12 and 13, the flash lamp 70 includes a light-emitting tube 71 in which a discharge gas is sealed, and a pair of electrodes (72, 73) disposed in the light-emitting tube 71. A terminal 70a on the electrode 72 side is electrically connected to an electrode 80a of the capacitor 80 via the inductor 81. A terminal 70b on the electrode 73 side is electrically connected to an electrode 80b of the capacitor 80 via the switching element 83 (cf. FIG. 12).

The switching element 83 can be switched between an on state and an off state by a control circuit (not illustrated), and controls electrical connection between the terminal 70b and the electrode 80b.

The resistor 82 is disposed in parallel with the switching element 83 and is electrically connected between a node N10, to which the terminal 70b of the flash lamp 70 and the switching element 83 are connected, and the electrode 80b of the capacitor 80.

The trigger circuit 91 is a circuit that applies a voltage to the trigger electrode 90 in order to cause dielectric breakdown in the light-emitting tube 71 of the flash lamp 70. The trigger electrode 90 is made of, for example, a metal rod made of tungsten, and is disposed such that a pair of electrodes (72, 73) extends in directions facing each other. As illustrated in FIG. 13, the trigger electrode 90 is disposed below the flash lamp 70 in the vertical direction.

FIG. 14 is a timing chart illustrating the operation of the lamp lighting device 100 according to FIG. 12. FIG. 14 illustrates a voltage V_{c} across the capacitor 80, a current I_{F} supplied to the flash lamp 70, and the timing for on-off control of the switching element 83. As illustrated in FIG. 14, the capacitor 80 is charged to a desired charged voltage V₁₀ by a power source (not illustrated). Thereafter, at timing t10, the trigger circuit 91 is driven.

When the trigger circuit 91 is driven and a voltage is applied to the trigger electrode 90 (timing t10), the discharge gas in the light-emitting tube 71 is ionized, and dielectric breakdown occurs between the pair of electrodes (72, 73). As a result, a discharge S10 is formed on the inner wall of the light-emitting tube 71 on the side close to the trigger electrode 90 (cf. FIG. 13). At this point, because the switching element 83 is in the off-state, the current I_{F} supplied from the capacitor 80 to the flash lamp 70 is limited by the resistor 82 (current I₁₀). As described above, the discharge S10 is maintained by a weak limited current limited by the resistor 82. As an example, the resistance value of the resistor 82 is about 10 kΩ.

Since being maintained by a weak limited current, the discharge S10 moves vertically upward with the lapse of time due to thermal convection in the light-emitting tube 71 (cf. FIG. 13). That is, after being formed near the inner wall of the light-emitting tube 71, the discharge S10 moves so as to approach the tube axis of the light-emitting tube 71.

At timing t20 when the discharge S10 approaches the tube axis of the light-emitting tube 71, the switching element 83 is switched to the on state. As a result, based on the charged voltage remaining in the capacitor 80, a large current is instantaneously supplied to the flash lamp 70 (current I₁₁), and the main discharge of the flash lamp 70 is executed. The discharge S10 formed between the pair of electrodes (72, 73) before execution of the main discharge may be referred to as “simmer discharge”.

By executing the main discharge of the flash lamp 70 in a state where the discharge S10 is close to the tube axis of the light-emitting tube 71, the occurrence of a main discharge near the inner wall of the light-emitting tube 71 is suppressed, and cloudiness is less likely to occur on the inner wall of the light-emitting tube 71. By suppressing occurrence of cloudiness in the light-emitting tube 71, a decrease in the output of the flash lamp 70 can be suppressed when flash irradiation is repeated, and as a result, resulting in a longer lifetime of the flash lamp 70.

In the configuration according to Patent Document 1, in order to float the discharge S10 by thermal convection, the current supplied to the flash lamp 70 needs to be a weak limited current. In this regard, according to intensive studies by the present inventors, it has been found that it is difficult to increase the energy efficiency of the flash lamp when flash irradiation is executed after simmer discharge in a case where the simmer current is set to a weak limited current. That is, there is room for improvement in terms of increasing energy efficiency when the flash lamp is flashed, while suppressing occurrence of cloudiness in the light-emitting tube through simmer discharge.

In view of the above, an object of the present invention is to provide a flash irradiation apparatus capable of suppressing a decrease in output when flash irradiation is repeated and having higher energy efficiency when a flash lamp is flashed than a conventional apparatus.

A flash irradiation apparatus according to the present invention includes: a flash lamp that includes a first terminal and a second terminal, and discharges when a voltage is applied between the first terminal and the second terminal; a capacitor including a first electrode electrically connectable to the first terminal and a second electrode electrically connectable to the second terminal; a first switching element that controls an electrical connection between the flash lamp and the capacitor; a second switching element that is disposed in parallel with the first switching element and controls an electrical connection between the flash lamp and the capacitor; and a controller that executes on-off control of the first switching element and the second switching element. The controller executes: a first control in which on-off control of the second switching element is repeatedly executed at high speed while the first switching element is in an off state, to apply a voltage from the capacitor in a charged state to the flash lamp; and a second control in which the first switching element is switched to an on state during execution of the first control, and a residual voltage of the capacitor remaining after the first control is applied to the flash lamp to generate a main discharge.

The present inventors have found that by repeating on-off control of the second switching element at high speed, a discharge formed in the flash lamp is expanded, and the discharge can be formed at a position away from the inner wall of the light-emitting tube included in the flash lamp. That is, by executing the first control before executing the second control, the occurrence of a main discharge near the inner wall of the light-emitting tube is suppressed. This makes it possible to suppress a decrease in the output of the flash lamp when flash irradiation is repeated.

Moreover, according to intensive studies by the present inventors, it has been found that the energy efficiency when the flash lamp is flashed is increased more than in the conventional apparatus by expanding the discharge through the first control. More specifically, execution of the first control promotes ionization of the discharge gas in the light-emitting tube, and execution of the second control after the first control efficiently generates a main discharge. This point will be described in detail in the section of “DETAILED DESCRIPTION OF THE PREFERRED EMBODIMENTS”.

The flash irradiation apparatus may further include an inductor disposed in parallel with the first switching element and disposed in series with the second switching element.

From the viewpoint of suppressing the energy of the capacitor consumed in the first control as much as possible, the off-time of the second switching element in the first control is preferably longer than the on-time of the second switching element. The above configuration is preferable in that the current supplied to the flash lamp in the first control can be adjusted by the inductor, and the off-time of the second switching element can be easily designed.

In the flash irradiation apparatus, the controller may be configured to execute the second control after executing the first control for a time of 40 msec or more and 100 msec or less.

Although details will be described later, according to the above configuration, it is easy to generate a main discharge in a state where the discharge is stably formed in the flash lamp, which is preferable.

In the flash irradiation apparatus, the controller may be configured to execute the second control after a lapse of a predetermined time from the start of the first control, and the predetermined time may be a time during which a discharge diameter of a discharge formed by the first control is half or more of a diameter of a light-emitting tube included in the flash lamp.

In the flash irradiation apparatus, after the second control is started, the controller may turn off the second switching element to stop the first control.

The flash irradiation apparatus may further include: a trigger electrode that is disposed along a tube axis direction of a light-emitting tube included in the flash lamp and assists in triggering the flash lamp; and a support unit that supports an irradiation target irradiated with a flash emitted from the flash lamp. The trigger electrode may be disposed outside a space sandwiched between the light-emitting tube and the irradiation target.

In an apparatus that irradiates an irradiation target such as a semiconductor wafer with a flash, for example, an auxiliary heating mechanism such as a halogen heater or a light-emitting diode (LED) may be disposed below the irradiation target in the vertical direction, and a flash lamp is typically mounted above the irradiation target in the vertical direction. Here, as represented by Patent Document 1, in the configuration in which the discharge formed in the flash lamp is floated by thermal convection to move the discharge away from the inner wall of the light-emitting tube, the trigger electrode needs to be disposed below the light-emitting tube in the vertical direction. In this case, since the trigger electrode is disposed in the space sandwiched between the light-emitting tube and the irradiation target, a portion of the flash emitted from the flash lamp is blocked by the trigger electrode, so that the irradiation target is hardly uniformly irradiated with the flash.

In contrast, in the above configuration, the discharge formed in the flash lamp is expanded by execution of the first control, and the discharge can be formed at a position away from the inner wall of the light-emitting tube of the flash lamp. That is, in the configuration in which the discharge formation position is moved away from the inner wall of the light-emitting tube by the first control, the installation position of the trigger electrode is not limited to a position below the light-emitting tube in the vertical direction. According to the above configuration, since the trigger electrode is disposed outside the space sandwiched between the light-emitting tube of the flash lamp and the irradiation target, the flash is not blocked by the trigger electrode, which is preferable. For example, the trigger electrode may be disposed above the light-emitting tube in the vertical direction.

According to the present invention, there is provided a flash irradiation apparatus capable of suppressing a decrease in output when flash irradiation is repeated and having higher energy efficiency when a flash lamp is flashed than a conventional apparatus.

### BRIEF DESCRIPTION OF THE DRAWINGS

FIG. 1 is a diagram illustrating a configuration of one embodiment of a flash irradiation apparatus according to the present invention;

FIG. 2 is a cross-sectional view illustrating a configuration example of a flash lamp;

FIG. 3 is a block diagram illustrating a configuration example of a controller;

FIG. 4 is a timing chart illustrating an example of the operation of the flash irradiation apparatus;

FIG. 5 is a view schematically illustrating a state of discharge in a light-emitting tube;

FIG. 6 is a diagram illustrating an example of a scene in which an irradiation target is irradiated with a flash;

FIG. 7 is a diagram illustrating a configuration of a flash irradiation apparatus used for verification of Comparative Example 1;

FIG. 8 is a graph illustrating an output characteristic of a flash irradiation apparatus in Example 1;

FIG. 9 is a graph illustrating evaluation results of the lifetime of the flash lamp;

FIG. 10 is a timing chart illustrating another example of the operation of the flash irradiation apparatus;

FIG. 11 is a diagram illustrating a configuration example of the flash irradiation apparatus according to FIG. 1;

FIG. 12 is a diagram schematically illustrating a circuit configuration of a lamp lighting device according to Patent Document 1;

FIG. 13 is a view schematically illustrating the configuration of the flash lamp according to FIG. 12; and

FIG. 14 is a timing chart illustrating the operation of the lamp lighting device according to FIG. 12.

### DETAILED DESCRIPTION OF THE PREFERRED EMBODIMENTS

Hereinafter, a configuration of a flash irradiation apparatus according to the present invention will be described with reference to the drawings. Note that each of the drawings described below is schematic illustration, and dimensional ratios and the numbers of components in the drawings do not necessarily coincide with actual dimensional ratios and the actual numbers of components.

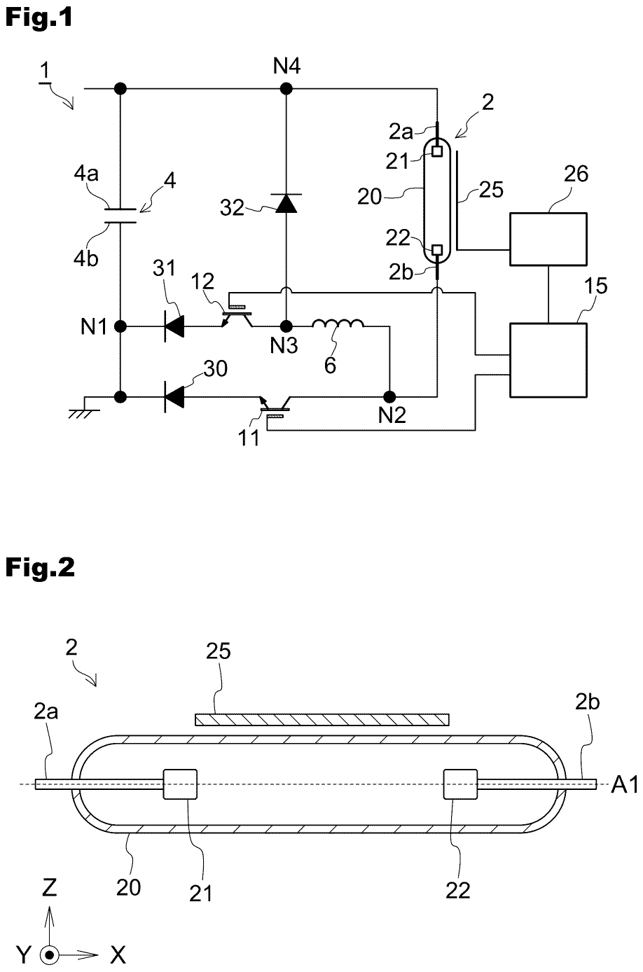

FIG. 1 is a diagram illustrating a configuration of an embodiment of the flash irradiation apparatus according to the present invention. As illustrated in FIG. 1, a flash irradiation apparatus 1 includes a flash lamp 2, a capacitor 4, an inductor 6, a first switching element 11, a second switching element 12, and a controller 15.

FIG. 2 is a cross-sectional view illustrating a configuration example of the flash lamp 2. FIG. 2 also illustrates an X-Y-Z coordinate system in which a direction parallel to a tube axis A1 of a light-emitting tube 20 is an X direction, and a plane orthogonal to the X direction is a Y-Z plane. In the following description, the coordinate system is referred to as appropriate. In the present embodiment, the Z direction corresponds to a vertically upward direction.

In the following description, when positive and negative directions are distinguished from each other in expressing a direction, each of the directions is represented with a positive or negative sign added, such as “+X direction” or “−X direction”. In the case of expressing a direction without distinguishing between positive and negative directions, the direction is simply represented as “X direction”. That is, in the present specification, when a direction is simply described as “X direction”, both “+X direction” and “−X direction” are included. The same applies to the Y direction and the Z direction.

As illustrated in FIG. 2, the flash lamp 2 includes the light-emitting tube 20 in which a discharge gas such as xenon is sealed, an anode 21, a cathode 22, a first terminal 2a including an electrode lead connected to the anode 21 side, and a second terminal 2b including an electrode lead connected to the cathode 22 side. The anode 21 and the cathode 22 are spaced apart from each other in the X direction, that is, in the direction of the tube axis A1 of the light-emitting tube 20.

As illustrated in FIG. 2, the flash lamp 2 includes a trigger electrode 25 disposed close to the outer peripheral surface of the light-emitting tube 20. As an example, the trigger electrode 25 is formed of a metal rod made of tungsten and is disposed to extend in the direction of the tube axis A1 of the light-emitting tube 20. In the present embodiment, the trigger electrode 25 is installed on the +Z side of the flash lamp 2, that is, above the flash lamp 2 in the vertical direction. As illustrated in FIG. 1, the trigger electrode 25 is configured to be capable of applying a trigger voltage by driving a trigger circuit 26.

The light-emitting tube 20 is made of a glass material such as quartz glass. As an example, a length of the light-emitting tube 20 in the X direction is 200 mm or more and 500 mm or less, and a thickness of the light-emitting tube 20 is 0.8 mm or more and 3 mm or less. Similarly, an outer diameter of the light-emitting tube 20 is 10 mm or more and 30 mm or less.

Although not illustrated, in the flash irradiation apparatus 1, the number of flash lamps 2 is not limited.

The anode 21 and the cathode 22 are made of a metal material such as tungsten, for example, and are disposed in the light-emitting tube 20. More specifically, the cathode 22 may be made of tungsten containing a substance (also referred to as an “emitter”) having an effect of reducing the work function. Examples of the emitter include barium aluminate, lanthanum oxide, and thorium oxide.

As illustrated in FIG. 1, the capacitor 4 includes a first electrode 4a electrically connectable to the first terminal 2a of the flash lamp 2 and a second electrode 4b electrically connectable to the second terminal 2b of the flash lamp 2. The first electrode 4a and the second electrode 4b can be connected to a power supply (not illustrated), and the capacitor 4 can be charged by the power supply.

As illustrated in FIG. 1, the first switching element 11 is disposed between a node N1 to which the second electrode 4b of the capacitor 4 is connected and a node N2 to which the second terminal 2b of the flash lamp 2 is connected. The first switching element 11 controls electrical connection between the second terminal 2b of the flash lamp 2 and the second electrode 4b of the capacitor 4. As illustrated in FIG. 1, a diode 30 is connected between the first switching element 11 and the node N1.

As illustrated in FIG. 1, the second switching element 12, in a state of being disposed in parallel with the first switching element 11, communicates with the node N1 and the node N2. The second switching element 12 controls electrical connection between the second terminal 2b of the flash lamp 2 and the second electrode 4b of the capacitor 4. In the present embodiment, the inductor 6 is connected between the second switching element 12 and the node N2. Similarly to the first switching element 11, a diode 31 is connected between the second switching element 12 and the node N1.

For example, each of the first switching element 11 and the second switching element 12 is formed of an insulated-gate bipolar transistor (IGBT), and the controller 15 controls a voltage applied to the control terminal to switch between an on state and an off state. The configuration of the controller 15 will be described later.

Note that it is optional whether each of the first switching element 11 and the second switching element 12 is formed of an IGBT. Any configuration can be adopted for each of the first switching element 11 and the second switching element 12 as long as the electrical connection state can be changed by a control signal from the controller 15.

The diode 30 is connected on the anode side to the first switching element 11, and prevents a reverse current from flowing into the first switching element 11 due to a back electromotive force. Similarly, the diode 31 is connected on the anode side to the second switching element 12, and prevents a reverse current from flowing into the second switching element 12. Note that the present invention is not limited to whether to include the diode (30, 31).

The inductor 6 has one terminal connected to the second switching element 12 at a node N3, and the other terminal connected to the node N2. That is, as illustrated in FIG. 1, the inductor 6 is disposed in parallel with the first switching element 11 and is disposed in series with the second switching element 12. The inductor 6 adjusts the time constant associated with the current supplied to the flash lamp 2 when the second switching element 12 is turned on. That is, the rising speed and the falling speed of the current supplied from the capacitor 4 to the flash lamp 2 are adjusted.

In the present embodiment, the flash irradiation apparatus 1 includes a diode 32 that connects the node N3 and a node N4 to which the first terminal 2a of the flash lamp 2 is connected (cf. FIG. 1). The anode of the diode 32 is disposed on the node N3 side, and the cathode is disposed on the node N4 side. As will be described later, the flash irradiation apparatus 1 preferably includes the diode 32 from the viewpoint of preventing a reverse current from flowing into the second switching element 12 due to a back electromotive force of the inductor 6 when on-off control of the second switching element 12 is executed. Further, by including the diode 32, the circuit can be easily protected when a high voltage, for example, 1000 V or more, is applied, which is preferable.

As illustrated in FIG. 1, the controller 15 is connected to the first switching element 11, the second switching element 12, and the trigger circuit 26. More specifically, the controller 15 is connected to the gate terminal of each of the first switching element 11 and the second switching element 12. The controller 15 is configured to transmit control signals to the first switching element 11 and the second switching element 12, and includes, for example, a processor such as a central processing unit (CPU) and a memory for storing information.

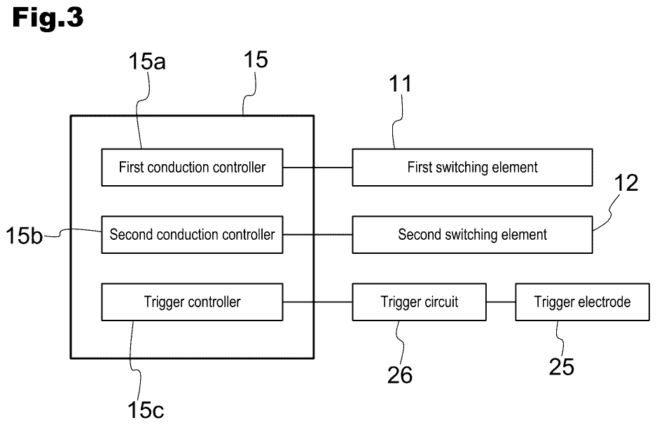

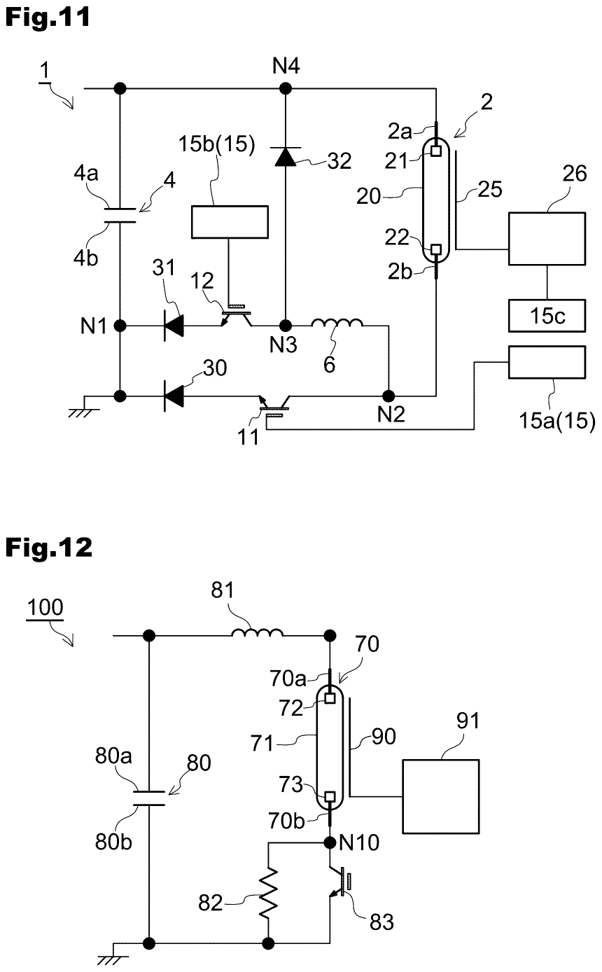

FIG. 3 is a block diagram illustrating a configuration example of the controller 15. As illustrated in FIG. 3, the controller 15 includes a first conduction controller 15a that controls an on state and an off state of the first switching element 11, a second conduction controller 15b that controls an on state and an off state of the second switching element 12, and a trigger controller 15c that controls a drive state of the trigger circuit 26. As will be described later with reference to FIG. 11, the first conduction controller 15a and the second conduction controller 15b may be configured separately.

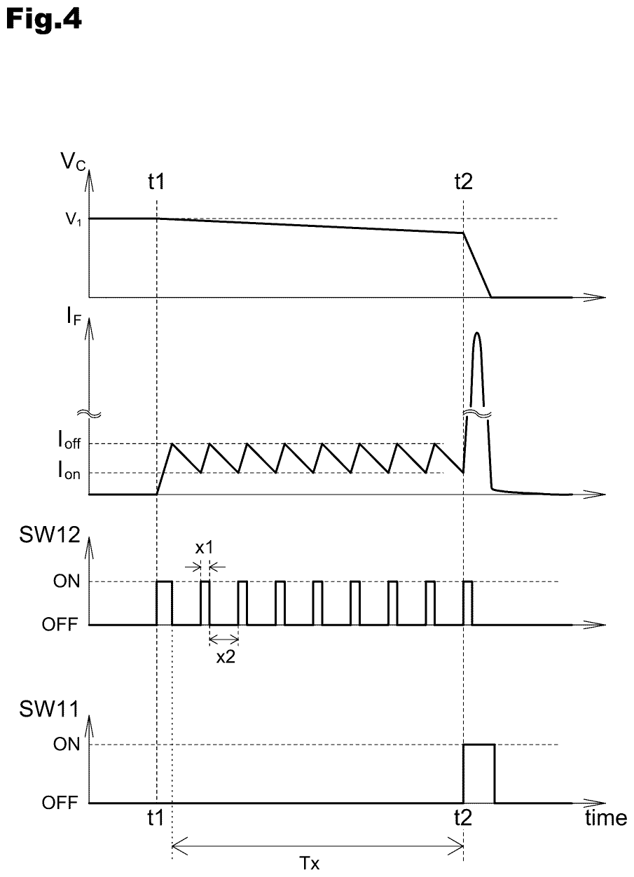

Next, an operation of the flash irradiation apparatus 1 will be described. FIG. 4 is a timing chart illustrating an example of the operation of the flash irradiation apparatus 1. FIG. 4 illustrates a voltage Ve across the capacitor 4, a current I_{F} supplied to the flash lamp 2, and the timing for on-off control of each of the first switching element 11 and the second switching element 12.

First, the capacitor 4 is charged by applying a voltage from a power supply (not illustrated). In FIG. 4, the capacitor 4 is charged to a desired voltage V1.

Next, at timing t1, the trigger circuit 26 is driven by the trigger controller 15c. At the same time, the second switching element 12 is turned on. As a result, a trigger voltage is applied from the trigger electrode 25 to the flash lamp 2. When the trigger voltage is applied, the gas in the light-emitting tube 20 is ionized, dielectric breakdown occurs, and discharge occurs between the anode 21 and the cathode 22. Then, due to the occurrence of the discharge, a current starts to flow through the flash lamp 2 via the path in which the second switching element 12 is disposed (cf. FIG. 1). In FIG. 4, the second switching element 12 is turned on simultaneously with the drive of the trigger circuit 26, but this is optional. For example, the second switching element 12 may be turned on at a timing before the trigger circuit 26 is driven.

As illustrated in FIG. 4, after driving the trigger circuit 26 at timing t1, the controller 15 repeatedly executes on-off control for switching between the on state and the off state of the second switching element 12 at high speed.

FIG. 4 schematically illustrates on-time x1 during which the second switching element 12 is in the on state and off-time x2 during which the second switching element 12 is in the off state. As an example, the controller 15 is configured to turn off the second switching element 12 at the time when the current I_{F} flowing through the flash lamp 2 reaches a predetermined current value I_{off}, and to turn on the second switching element 12 at the time when the current I_{F} reaches a predetermined current value Iₒₙ. For example, the controller 15 includes a storage (not illustrated), and executes on-off control of the second switching element 12 based on information stored in the storage. Note that the controller 15 may execute on-off control of the second switching element 12 based on the on-time x1 and the off-time x2 determined in advance.

The rising speed and the falling speed of the current flowing through the flash lamp 2 can be adjusted by, for example, the design of the inductor 6.

The present inventors have found that by repeatedly executing on-off control of the second switching element 12 to supply a current to the flash lamp 2, a discharge formed between the anode 21 and the cathode 22 is expanded, and that, compared to the time of the start, the discharge can be formed at a position farther away from the inner wall of the light-emitting tube 20, and more specifically, at a position closer to the tube axis A1 of the light-emitting tube 20.

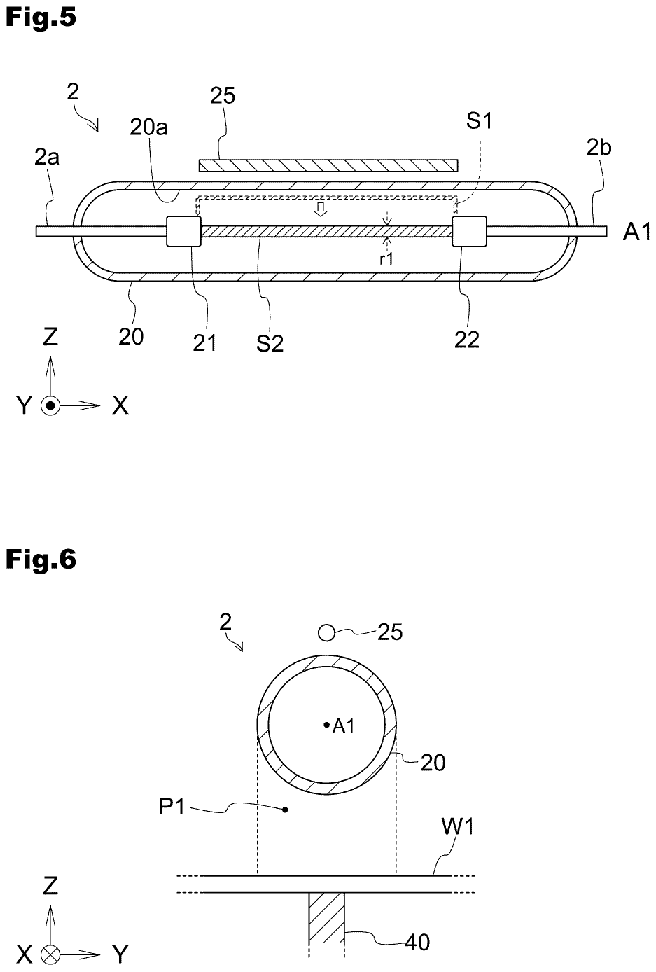

FIG. 5 is a view schematically illustrating a state of discharge in the light-emitting tube 20. As illustrated in FIG. 5, when a trigger voltage is applied and dielectric breakdown occurs in the light-emitting tube 20, a discharge S1 is formed near an inner wall 20a of the light-emitting tube 20 on the side close to the trigger electrode 25. Thereafter, on-off control of the second switching element 12 is repeatedly executed, and a current is supplied to the flash lamp 2, whereby the discharge S1 grows and expands, and a discharge diameter r1 of the discharge S1 increases, as illustrated in FIG. 5. As a result of expansion by on off control of the second switching element 12, the discharge S1 is formed at a position farther away from the inner wall 20a of the light-emitting tube 20 compared to the time of the start (discharge S2). In FIG. 5, the position of the discharge S1 immediately after the start is indicated by a broken line, and the position of the discharge S2 after the expansion is indicated by a solid line.

As described above, the control in which the controller 15 switches between the on state and the off state of the second switching element 12 at high speed corresponds to the “first control”.

As illustrated in FIG. 4, after a predetermined time Tx has elapsed since the start of on-off control (first control) of the second switching element 12, the controller 15 turns on the first switching element 11 at timing t2. As a result, a large current is instantaneously supplied to the flash lamp 2 based on the charged voltage remaining in the capacitor 4, and the main discharge of the flash lamp 2 is executed. As an example, the controller 15 turns on the first switching element 11 based on information stored in any suitable storage (not illustrated).

The control in which the controller 15 switches the first switching element 11 to the on-state after the first control to generate a main discharge corresponds to the “second control”.

As described with reference to FIG. 5, the discharge S2 is formed at a position away from the inner wall 20a by execution of the first control. By executing the second control in this state, the occurrence of a main discharge near the inner wall 20a is suppressed, and cloudiness of the inner wall 20a is less likely to occur. Therefore, it is possible to suppress a decrease in the output of the flash lamp 2 when flash irradiation is repeated.

Moreover, by supplying a current while executing on-off control of the second switching element 12 at high speed to expand the discharge S2, it is possible to increase energy efficiency when the flash lamp 2 is flashed. This point will be described in detail in the section of “Verification 2”.

As illustrated in FIG. 4, after the first switching element 11 is turned on (second control), the controller 15 holds the second switching element 12 in the off state and stops the first control.

The second switching element 12 may be turned off simultaneously with the first switching element 11 being turned on. However, even when the controller 15 simultaneously transmits control signals to the first switching element 11 and the second switching element 12, there may be a difference between the timing at which the first switching element 11 is turned on and the timing at which the second switching element 12 is turned off. In this case, there is a possibility that the discharge S2 is reduced from the time when the second switching element 12 is turned off to the time when the first switching element 11 is turned on. In view of this, the first control is preferably stopped after the start of the second control.

In the second switching element 12, as a result of repeated on-off control, a current smaller than that in the first switching element 11 flows. In view of this, the rated current of the second switching element 12 may be made smaller than the rated current of the first switching element 11. As an example, the rated current of the second switching element 12 may be within a range of 1 A or more and 100 A or less. The rated current of the first switching element 11 may be in a range of 1000 A or more and 5000 A or less.

As described above, the discharge S2 is formed near the tube axis A1 of the light-emitting tube 20 by on-off control (first control) of the second switching element 12. By executing the second control in this state, the main discharge of the flash lamp 2 can be generated starting from the discharge S2. This suppresses the occurrence of a main discharge near the inner wall 20a of the light-emitting tube 20, and cloudiness of the inner wall 20a is less likely to occur, resulting in a longer lifetime of the flash lamp 2.

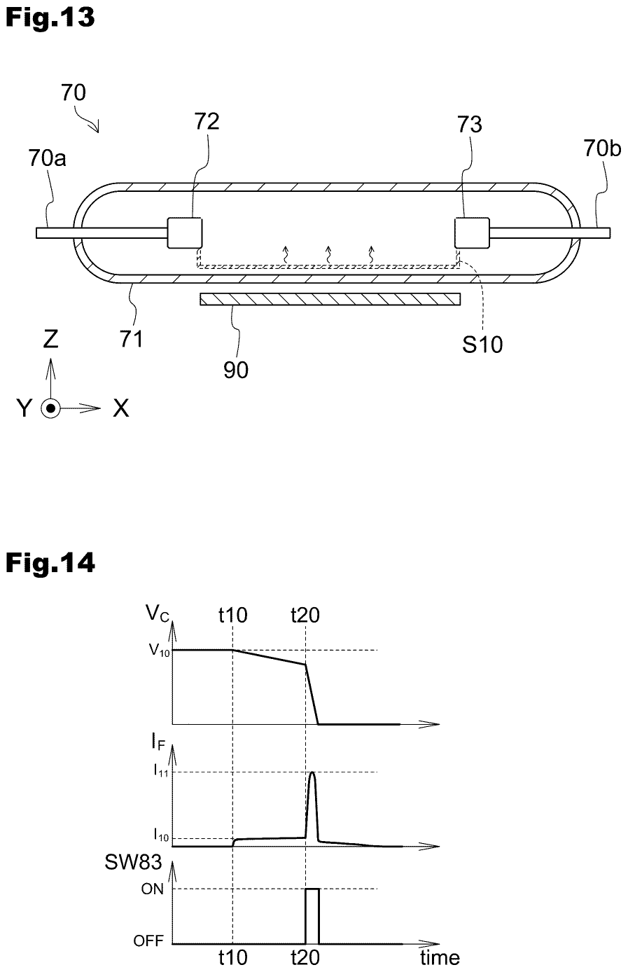

That is, according to the present embodiment, as described with reference to FIGS. 12 to 14, the discharge S2 can be formed near the tube axis A1 of the light-emitting tube 20, similarly to a case where a discharge between electrodes is floated by thermal convection. In the example of FIG. 12, the trigger electrode needs to be disposed below the light-emitting tube 71 in the vertical direction (−Z side) in order to float the discharge S10. In contrast, in the present embodiment, since the discharge S2 is expanded by on-off control of the second switching element 12, the installation position of the trigger electrode 25 is not limited.

FIG. 6 is a diagram illustrating an example of a scene where an irradiation target is irradiated with a flash. FIG. 6 corresponds to the drawing when the flash lamp 2 is viewed in the X direction. As illustrated in FIG. 6, the flash irradiation apparatus 1 includes a support unit 40 that supports an irradiation target W1 on the −Z side of the flash lamp 2, that is, the side below the flash lamp 2 in the vertical direction. The irradiation target W1 is, for example, a semiconductor wafer such as a silicon substrate. As an example, the support unit 40 is configured to support the irradiation target W1 by negative pressure formed by a suction mechanism (not illustrated). The configuration of the support unit 40 is not limited as long as the irradiation target W1 can be supported in a state where the main surface of the irradiation target W1 is parallel to the XY plane. For example, the support unit 40 may include a plurality of pin-shaped protrusions and support the irradiation target W1 by the protrusions.

When the irradiation target W1 is irradiated with a flash, the flash lamp 2 is typically mounted above the irradiation target W1 in the vertical direction (+Z side), as illustrated in FIG. 6. Here, if the trigger electrode is disposed below the flash lamp 2 in the vertical direction (−Z side), a portion of the flash emitted from the flash lamp 2 is blocked by the trigger electrode, and as a result, it becomes difficult to uniformly irradiate the irradiation target W1 with the flash. In contrast, in the present embodiment, the trigger electrode 25 is disposed above the light-emitting tube 20 in the vertical direction (+Z side), so that the flash is not blocked by the trigger electrode 25, which is preferable.

In view of the above, the trigger electrode 25 is preferably disposed outside a space P1 (cf. FIG. 6) sandwiched between the light-emitting tube 20 and the irradiation target W1. This can prevent a portion of the flash emitted from the flash lamp 2 from being blocked by the trigger electrode 25. More preferably, the trigger electrode 25 is disposed on the opposite side of the irradiation target W1 with respect to the light-emitting tube 20.

### [Verification 1]

Since it has been confirmed that the lifetime of the flash lamp 2 can be extended by repeatedly executing on-off control of the second switching element 12 before execution of the main discharge, the details will be described below.

### Example 1

The flash irradiation apparatus described with reference to FIG. 1 was prepared, the on-off control (first control) of the second switching element 12 was repeatedly executed at high speed, and then the second control was executed to generate a main discharge of the flash lamp 2 (cf. also FIG. 4).

In the present verification, the operation from charging the capacitor 4 to a predetermined voltage to generating a main discharge of the flash lamp 2 was repeated about 100,000 times, and the transition of the output of the flash lamp 2 was confirmed. Detailed conditions are shown below.
Electric capacitance of capacitor: 200 μF
Current value I_{off} for turning off second switching element 12 in first control: 9A
Current value Iₒₙ for turning on second switching element 12 in first control: 6A
Time Tx from start of first control to execution of second control: 80 msec
Inner diameter of light-emitting tube 20 of flash lamp 2: 10 mm
Discharge gas xenon: (Encapsulation pressure: 60 kPa)
Interval between anode 21 and cathode 22: 400 mm

### Comparative Example 1

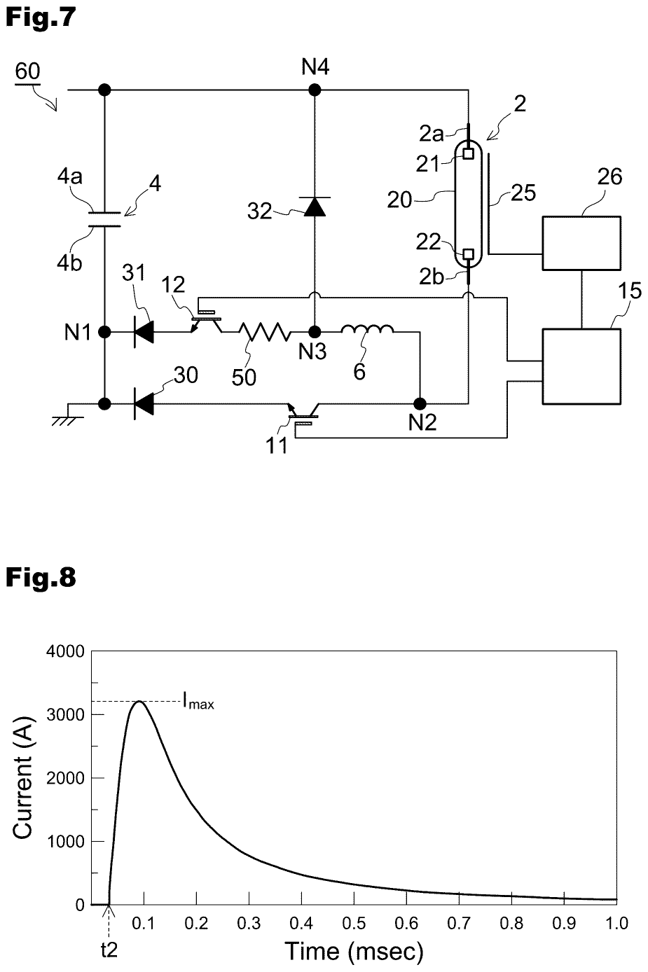

FIG. 7 is a diagram illustrating a configuration of a flash irradiation apparatus used for verification of Comparative Example 1. In FIG. 7, elements common to those in FIG. 1 are denoted by common reference numerals. In a flash irradiation apparatus 60, as illustrated in FIG. 7, a resistor 50 is disposed between the node N3 and the second switching element 12. In Comparative Example 1, the trigger circuit 26 is driven while the first switching element 11 is in the off state and the second switching element 12 is in the on state, and the limited current limited by the resistor 50 is supplied to the flash lamp 2.

In Comparative Example 1, the trigger electrode 25 was installed below the light-emitting tube 20 in the vertical direction. That is, in Comparative Example 1, the discharge formed by application of the trigger voltage is floated by thermal convection while being maintained at the limited current. Comparative Example 1 differs from Example 1 in that, after the trigger circuit is driven, the limited current is supplied for a predetermined time without execution of the first control in which on-off control of the second switching element 12 is repeatedly executed, and then, the main discharge is executed.

The limited current was set to about 0.1 A, and the main discharge was executed at a timing when the discharge formed between the pair of electrodes approached the tube axis of the light-emitting tube 20. The time to supply the limited current was 80 msec.

Then, the operation from the charging of the capacitor 4 to the generation of the main discharge of the flash lamp 2 was repeated about 100,000 times, and the transition of the output of the flash lamp 2 was confirmed. It is noted that, in Comparative Example 1, the residual voltage of the capacitor 4 at the time of execution of the main discharge was set equal to the residual voltage at the time of execution of the main discharge (time t2) of Example 1.

### [Result of Verification 1]

FIG. 8 is a graph illustrating an output characteristic of the flash irradiation apparatus in Example 1. In FIG. 8, the vertical axis represents the current value supplied to the flash lamp, and the horizontal axis represents the elapsed time from the application of the trigger voltage. FIG. 8 schematically illustrates timing t2 at which the first switching element 11 is turned on after execution of a simmer discharge. It can be understood from FIG. 8 that, after the first switching element 11 is turned on, a large current is instantaneously supplied to the flash lamp 2, thereby causing the main discharge to occur.

It is preferable to shorten the flash irradiation time of the flash lamp 2 from the viewpoint of suppressing impurity diffusion during flash irradiation of the irradiation target W1 such as a semiconductor wafer. Specifically, the flash irradiation time is preferably 1 sec or less, and more preferably 100 msec or less. The flash irradiation time may be a half width of a graph indicating the current value with respect to the elapsed time. Referring to FIG. 8, the flash irradiation time is about 0.14 msec, and it can be understood that the flash irradiation apparatus 1 can be suitably applied to flash irradiation of a semiconductor wafer or the like.

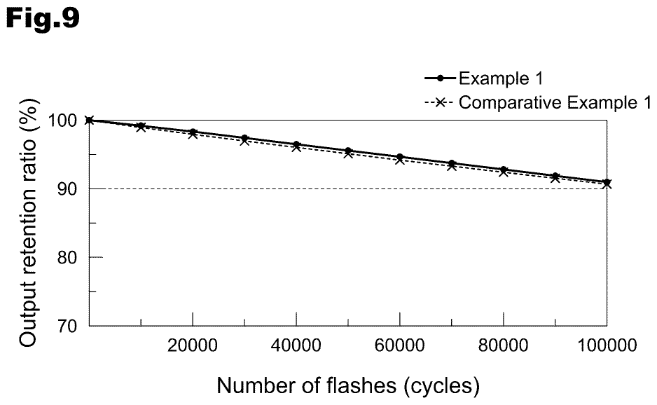

FIG. 9 is a graph illustrating evaluation results of the lifetime of the flash lamp 2. In FIG. 9, the vertical axis represents the output retention ratio of the flash lamp, and the horizontal axis represents the number of flash cycles of the flash lamp. The output retention ratio of the flash lamp was defined as the ratio of the maximum current Imax at each lighting to the maximum current Imax at the first lighting.

As illustrated in FIG. 9, in Comparative Example 1, the output retention ratio after 100,000 times of lighting was about 90%, and a favorable lifetime characteristic was obtained. In Comparative Example 1, the main discharge was executed at the timing when the discharge formed between the pair of electrodes approached the tube axis of the light-emitting tube 20. As a result, it can be seen that the occurrence of a main discharge near the inner wall of the light-emitting tube 20 is suppressed, and a decrease in the output of the flash lamp due to occurrence of cloudiness in the inner wall is suppressed.

As illustrated in FIG. 9, also in Example 1, the output retention ratio after 100,000 times of lighting was about 90%, and a favorable lifetime characteristic was obtained as in Comparative Example 1. As described with reference to FIG. 5, by repeatedly executing on-off control of the second switching element 12 (first control), the discharge S2 can be formed at a position away from the inner wall 20a of the light-emitting tube 20. That is, it is considered that execution of the second control for generating a main discharge after execution of the first control suppressed the occurrence of a main discharge near the inner wall 20a, and as a result, a decrease in the output of the flash lamp was suppressed as in Comparative Example 1. The present verification showed that by generating a main discharge after repeatedly executing on-off control of the second switching element 12, it is possible to suppress a decrease in the output of the flash lamp when the main discharge is repeated.

### [Verification 2]

Next, the influence of the first control of repeatedly executing on-off control of the second switching element 12 on the energy efficiency of the flash lamp has been verified and will thus be described below with reference to Examples.

### Example 2

In Example 1 in Verification 1 above, the time Tx from the start of the first control to execution of the second control was changed to 5 msec. In the present verification, the voltage remaining in the capacitor at the time of execution of the second control was set to about 3600 V. Then, an output Oₚ of the flash lamp during the main discharge was measured by a calorimeter (Ophir-made L30A-SH-V1), and an energy efficiency O_{E} of the flash lamp was obtained from the following equation (1). In the following equation (1), U corresponds to the charged energy of the capacitor at time t2. Note that the measurement of the output Oₚ was performed five times, and the average value thereof was adopted.

$${O}_{E} = {O}_{p} / U \qquad ( 1 )$$

### Example 3

The present example was carried out under the same conditions as those in Example 2, except that the time Tx was changed to 45 msec.

### Example 4

The present example was carried out under the same conditions as those in Example 2, except that the time Tx was changed to 80 msec.

### Comparative Example 2

Under the same conditions as those in Comparative Example 1 in Verification 1 above, the discharge formed between the pair of electrodes was floated by thermal convection while being maintained at the limited current, and then the main discharge of the flash lamp was executed. The point that the voltage remaining in the capacitor at the time of execution of the main discharge is adjusted to 3600 V, and the method for measuring the energy efficiency O_{E} of the flash lamp, are the same as those in Example 2.

### [Result of Verification 2]

Table 1 below shows results of a comparison of the energy efficiency O_{E} in the respective examples. In Table 1, relative values based on the energy efficiency O_{E} of Comparative Example 2 are shown for each example.

TABLE 1

| | Relative energy efficiency O_{E} |
|---|---|
| | (vs. Comparative Example 2) |
| Example 2 | 1.05 |
| Example 3 | 1.19 |
| Example 4 | 1.21 |

According to Table 1, it can be understood that the energy efficiency of Example 2 is greater than the energy efficiency of Comparative Example 2. The same applies to Examples 3 and 4. Although the voltage remaining in the capacitor at the time of execution of the main discharge was the same, the energy efficiency of the flash lamp was improved more by expanding the discharge through on-off control of the second switching element 12 than by floating the discharge by thermal convection. In this regard, the present inventors assume as follows. That is, it is considered that, instead of supplying a weak limited current to the flash lamp in order to allow the discharge to separate from the inner wall by thermal convection, repeatedly supplying a current of several amperes promotes ionization of the discharge gas in the light-emitting tube 20. As a result, the energy required for ionization in the main discharge during flash irradiation is reduced, and the luminous efficiency of the main discharge is improved. That is, it can be said that it is difficult to increase the energy efficiency of the flash lamp in the case of forming a simmer discharge with a weak limited current.

According to the present verification, it was shown that the energy efficiency when the flash lamp is flashed can be further increased by expanding the discharge S2 through the first control, in which on-off control of the second switching element 12 is repeatedly performed at high speed, than by floating the discharge between the electrodes by thermal convection.

### [Verification 3]

For further consideration, a comparative verification between Example 4 and Comparative Example 3 described below was performed. In the present verification, in each case, the voltage drop from the charged voltage of the capacitor 4 to the voltage at the time of execution of the main discharge, and the energy efficiency O_{E}, were compared.

### Comparative Example 3

The present example was carried out under the same conditions as those in Example 4, except that, after the trigger circuit 26 was driven with the first switching element 11 in the off state and the second switching element 12 in the on state, a current was supplied to the flash lamp 2 until the main discharge was executed while the second switching element 12 was held in the on state.

### [Result of Verification 3]

In Example 4, the voltage drop from the charged voltage of the capacitor 4 to the voltage (3600 V) at the time of execution of the main discharge was about 300 V. In contrast, the voltage drop of Comparative Example 3 was about 450 V. When the energy efficiency O_{E} was calculated based on the above equation (1), the energy efficiency O_{E} was about the same in Example 4 and Comparative Example 3. That is, in Example 4, consumption of the charged voltage of the capacitor 4 was suppressed more than in Comparative Example 3, while an equivalent level of energy efficiency O_{E} was obtained.

That is, according to the present verification, it has been found that, when a current is supplied to the flash lamp 2 to expand the discharge in the light-emitting tube 20 before execution of the main discharge, consumption of the charged voltage of the capacitor 4 is suppressed by repeatedly executing on-off control of the second switching element 12 at high speed, rather than holding the second switching element 12 in the on state.

### [Consideration]

From the results of Verification 1, it can be seen that according to Example 4, a favorable lifetime characteristic can be obtained as in Comparative Example 1. In Example 4, the energy efficiency of the flash lamp was increased while a favorable lifetime characteristic was achieved, thereby obtaining a preferable result.

Moreover, when the present inventors observed the discharge formed in the flash lamp 2 by using a high-speed camera, it was confirmed that the discharge between the electrodes was located near the inner wall 20a of the light-emitting tube 20 at an elapsed time of 0.5 msec from the start of the first control (discharge S1 in FIG. 5), that the discharge started to expand at an elapsed time of 10 msec, and that the formation region varied. Then, after about 40 msec, it was confirmed that the discharge was stably formed at a position centered on the tube axis A1 of the light-emitting tube 20.

In view of this, also in Example 3 in which the time Tx from the start of the first control to execution of the second control is 45 msec, it can be said that a favorable lifetime characteristic can be obtained as in Example 1. In view of the fact that the formation region of the discharge between the electrodes varies at an elapsed time of about 10 msec, it can be expected that an effect of moving the discharge away from the inner wall 20a is exhibited by execution of the first control for about several msec. It is considered that the lifetime characteristic is also improved in Example 2 in which the time Tx is set to 5 msec.

At an elapsed time of 40 msec from the start of the first control, the discharge diameter r1 of the discharge between the electrodes (cf. FIG. 5) reached about a half of the inner diameter (10 mm) of the light-emitting tube 20. It is thereby considered that, when the time Tx was set to 45 msec or more, the discharge diameter r1 became larger, further increasing the energy efficiency (cf. Table 1).

As described above, from the results of Verification 1 and Verification 2, it has been shown that by generating a main discharge after repeatedly executing on-off control of the second switching element 12, the energy efficiency of the flash lamp is increased while the favorable lifetime characteristic of the flash lamp is realized. Moreover, from the result of Verification 3, by adopting a configuration in which on-off control of the second switching element 12 is repeatedly executed, it is possible to suppress a decrease in the charged voltage of the capacitor 4 during simmer discharge.

That is, according to the above embodiment, it is possible to suppress a decrease in output when flash irradiation is repeated, and it is possible to increase energy efficiency when the flash lamp is turned on more than in a conventional apparatus.

As described above, when the time Tx from the start of the first control to execution of the second control is set to 40 msec or more, the discharge S2 can be easily formed stably. In view of this, the time Tx is preferably set to 40 msec or more. Further, by setting the time Tx to 40 msec or more, the energy efficiency O_{E} can be greatly improved, which is more preferable (cf. Table 1). When the time Tx becomes too long, the charged voltage of the capacitor 4 tends to decrease. In view of this, the time Tx is preferably set to 100 msec or less.

Moreover, in view of facilitating expansion of the discharge in the light-emitting tube 20 before execution of the main discharge, the current value Iₒₙ for switching the second switching element 12 to the on-state in the first control is preferably 3 A or more, and more preferably 5 A or more. From a similar viewpoint, in the first control, the current value I_{off} for switching the second switching element 12 to the off state is preferably 7 A or more, and more preferably 9 A or more. It is considered that, when the current value I_{off} is too large, the charged voltage of the capacitor 4 tends to decrease earlier. In view of this, the current value Loff is preferably 10 A or less, and more preferably 8 A or less.

In addition, from the viewpoint of easily suppressing the consumption of the charged voltage of the capacitor 4 in the first control, the off-time x2 of the second switching element 12 is preferably longer than the on-time x1 (cf. also FIG. 4). As an example, the ratio of the on-time x1 to the off-time x2 is 10% or less. As a detailed specific example, the on-time x1 is 5 μsec or more and 30 μsec or less. The off-time x2 is 50 μsec or more and 1000 μsec or less. When the off-time x2 is too long, it is assumed that simmer discharge disappears. In view of this, the off-time x2 is preferably set to 500 μsec or less.

In view of the above, on-off control of the second switching element 12 is preferably executed at high speed on the order of 1 msec or less.

### (Modifications)

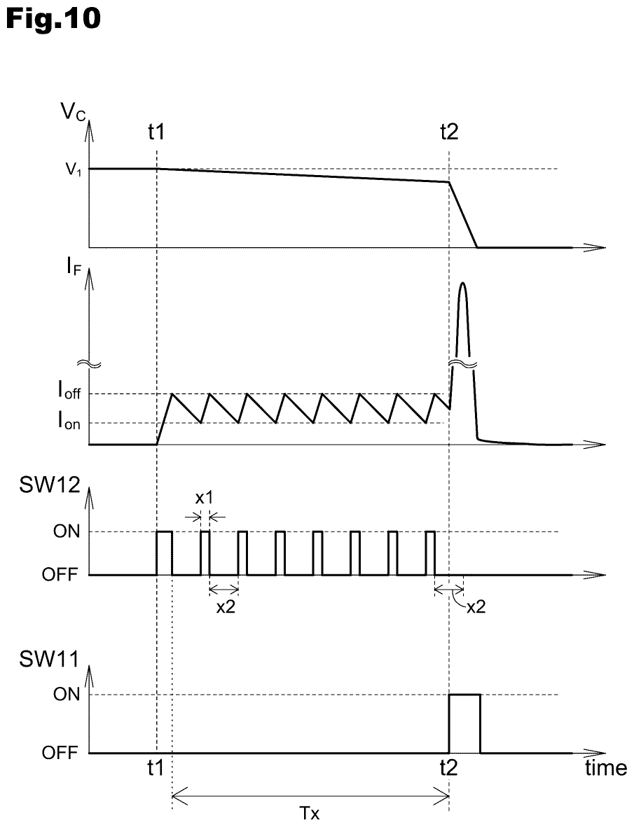

Hereinafter, modifications of the flash irradiation apparatus 1 will be described.
<1> As described above, in the first control, the off-time x2 of the second switching element 12 is preferably longer than the on-time x1. From the viewpoint of facilitating the adjustment of the off-time x2, the flash irradiation apparatus 1 preferably includes the inductor 6 disposed in parallel with the first switching element 11 and disposed in series with the second switching element 12, as illustrated in FIG. 1. However, in the present invention, it is optional whether the flash irradiation apparatus 1 includes the inductor 6.
<2> In the above description, it has been described that the first electrode 4a of the capacitor 4 and the first terminal 2a of the flash lamp 2 are connected without a circuit element interposed therebetween (cf. FIG. 1). However, from the viewpoint of adjusting the flash irradiation time of the flash lamp 2, the flash irradiation apparatus 1 may include an inductor connected in series with the flash lamp 2, for example, between the first electrode 4a and the first terminal 2a.
<3> FIG. 10 is a timing chart illustrating another example of the operation of the flash irradiation apparatus 1 in accordance with FIG. 4. In the above description, it has been described that, after the first switching element 11 is turned on, the second switching element 12 is held in the off state, and the first control is stopped (cf. FIG. 4). However, as illustrated in FIG. 10, the first switching element 11 may be turned on after the second switching element 12 is turned off.

In FIG. 10, even after the second switching element 12 is turned off, the discharge S2 continues until at least the off-time x2 elapses. That is, a period until the off-time x2 elapses after the second switching element 12 is turned off may be defined as a period during which the first control is executed.
<4> As described with reference to FIG. 5, when the main discharge is executed in a state where the discharge S2 is formed at a position away from the inner wall 20a of the light-emitting tube 20, occurrence of cloudiness in the inner wall 20a can be suppressed. By increasing the discharge diameter r1 before execution of the main discharge, ionization of the discharge gas proceeds in the light-emitting tube 20, and energy efficiency when the flash lamp is flashed is increased. Specifically, the main discharge is preferably executed after the discharge S2 is expanded and the discharge diameter r1 of the discharge S2 becomes half or more of the inner diameter of the light-emitting tube 20 (cf. FIG. 5). Here, in view of the fact that the thickness of the light-emitting tube 20 is typically as small as 3 mm or less, the diameter of the light-emitting tube 20 used for comparison with the discharge diameter r1 may be the outer diameter of the light-emitting tube 20.

The time required for the discharge diameter r1 of the discharge S2 to become half or more of the diameter of the light-emitting tube 20 can be measured in advance, for example, by observing the discharge S2 with a high-speed camera or the like. Therefore, the controller 15 may include a storage unit, such as a memory, and a time during which the discharge diameter r1 becomes half or more of the diameter of the light-emitting tube 20 may be stored in the memory. Then, based on the time, the controller 15 may determine the time Tx from the start of the first control to execution of the second control.
<5> FIG. 11 is a diagram illustrating a configuration example of the flash irradiation apparatus 1 in conformity with FIG. 1. In the above description, it has been described that the controller 15 includes the first conduction controller 15a and the second conduction controller 15b. However, as illustrated in FIG. 11, in the flash irradiation apparatus 1, the first conduction controller 15a and the second conduction controller 15b may be configured separately. The same applies to the trigger controller 15c.
<6> In the above description, it has been described that the first switching element 11 and the second switching element 12 are disposed between the node N1 and the node N2. However, the arrangement of the first switching element 11 and the second switching element 12 is not limited to the above as long as the electrical connection between the flash lamp 2 and the capacitor 4 can be controlled. For example, the first switching element 11 and the second switching element 12 may be disposed between the first terminal 2a of the flash lamp 2 and the first electrode 4a of the capacitor 4. From the viewpoint of facilitating the design of the reference potential in the switching element, the first switching element 11 and the second switching element 12 preferably control the electrical connection between the second terminal 2b and the second electrode 4b disposed on the ground side (cf. FIG. 1, etc.).
<7> The configuration of the flash irradiation apparatus 1 according to the present invention is not limited to the embodiment described above.

### DESCRIPTION OF REFERENCE SIGNS

1 Flash irradiation apparatus
2 Flash lamp
2a First terminal
2b Second terminal
4 Capacitor
4a First electrode
4b Second electrode
6 Inductor
11 First switching element
12 Second switching element
15 Controller
15a First conduction controller
15b Second conduction controller
15c Trigger controller
20 Light-emitting tube
21,22 Anode, Cathode
25 Trigger electrode
26 Trigger circuit
30,31,32 Diode
40 Support unit

What is claimed is:

1. A flash irradiation apparatus comprising:
a flash lamp that includes a first terminal and a second terminal, and discharges when a voltage is applied between the first terminal and the second terminal;
a capacitor including a first electrode electrically connectable to the first terminal and a second electrode electrically connectable to the second terminal;
a first switching element that controls an electrical connection between the flash lamp and the capacitor;
a second switching element that is disposed in parallel with the first switching element and controls an electrical connection between the flash lamp and the capacitor; and
a controller that executes on-off control of the first switching element and the second switching element,
wherein the controller executes:
a first control in which on-off control of the second switching element is repeatedly executed at high speed while the first switching element is in an off state, to apply a voltage from the capacitor in a charged state to the flash lamp, and
a second control in which the first switching element is switched to an on state during execution of the first control, and a residual voltage of the capacitor remaining after the first control is applied to the flash lamp to generate a main discharge.

2. The flash irradiation apparatus according to claim 1, further comprising an inductor disposed in parallel with the first switching element and disposed in series with the second switching element.

3. The flash irradiation apparatus according to claim 1, wherein the controller is configured to execute the second control after executing the first control for a time of 40 msec or more and 100 msec or less.

4. The flash irradiation apparatus according to claim 2, wherein the controller is configured to execute the second control after executing the first control for a time of 40 msec or more and 100 msec or less.

5. The flash irradiation apparatus according to claim 2, wherein in the first control, an off-time of the second switching element is longer than an on-time of the second switching element.

6. The flash irradiation apparatus according to claim 1, wherein, the controller turns off the second switching element to stop the first control after the second control is started.

7. The flash irradiation apparatus according to claim 2, wherein, the controller turns off the second switching element to stop the first control after the second control is started.

8. The flash irradiation apparatus according to claim 1, wherein
the controller is configured to execute the second control after a lapse of a predetermined time from start of the first control, and
the predetermined time is a time during which a discharge diameter of a discharge formed by the first control is half or more of a diameter of a light-emitting tube included in the flash lamp.

9. The flash irradiation apparatus according to claim 2, wherein
the controller is configured to execute the second control after a lapse of a predetermined time from start of the first control, and
the predetermined time is a time during which a discharge diameter of a discharge formed by the first control is half or more of a diameter of a light-emitting tube included in the flash lamp.

10. The flash irradiation apparatus according to claim 1, further comprising:
a trigger electrode that is disposed along a tube axis direction of a light-emitting tube included in the flash lamp and assists in triggering the flash lamp; and
a support unit that supports an irradiation target irradiated with a flash emitted from the flash lamp,
wherein the trigger electrode is disposed outside a space sandwiched between the light-emitting tube and the irradiation target.

11. The flash irradiation apparatus according to claim 2, further comprising:
a trigger electrode that is disposed along a tube axis direction of a light-emitting tube included in the flash lamp and assists in triggering the flash lamp; and
a support unit that supports an irradiation target irradiated with a flash emitted from the flash lamp,
wherein the trigger electrode is disposed outside a space sandwiched between the light-emitting tube and the irradiation target.
